(19) United States
(12) Patent Application Publication
(10) Pub. No.: US 2020/0045859 A1
(43) Pub. Date: Feb. 6, 2020

(54) ELECTROMAGNETIC-WAVE-ABSORBING COMPOSITE SHEET

(71) Applicants: Seiji KAGAWA, Koshigaya-shi (JP); Atsuko KAGAWA, Koshigaya-shi (JP)

(72) Inventor: Seiji KAGAWA, Koshigaya-shi (JP)

(73) Assignees: Seiji Kagawa, Koshigaya-shi (JP); Atsuko Kagawa, Koshigaya-shi (JP)

(21) Appl. No.: 16/440,791

(22) Filed: Jun. 13, 2019

(30) Foreign Application Priority Data
Aug. 2, 2018 (JP) 2018-145742

(51) Int. Cl. H05K 9/00; B32B 15/08; B32B 9/00; B32B 27/08; B32B 27/20; B32B 7/12

(52) U.S. Cl. CPC H05K 9/0088; H05K 9/0083; H05K 9/0084; H05K 9/0075; B32B 15/08; B32B 9/005; B32B 2307/208; B32B 27/20; B32B 7/12; B32B 2264/105; B32B 2255/10; B32B 2255/205; B32B 2307/212; B32B 27/08

(57) ABSTRACT

An electromagnetic-wave-absorbing composite sheet comprising an electromagnetic-wave-absorbing magnetic film, and an electromagnetic-wave-shielding film laminated on the electromagnetic-wave-absorbing magnetic film; the electromagnetic-wave-absorbing magnetic film comprising magnetic powder uniformly dispersed in a binder resin; the electromagnetic-wave-shielding film being a conductive metal foil, a plastic film having a thin conductive metal film or coating, or a carbon sheet; and an area ratio of the electromagnetic-wave-shielding film to the electromagnetic-wave-absorbing magnetic film being 10-80%.

### FIELD OF THE INVENTION

The present invention relates to an electromagnetic-wave-absorbing composite sheet having high absorbability to electromagnetic wave noises in a desired frequency range, and capable of shifting a frequency range in which electromagnetic wave noise absorbability is maximized.

### BACKGROUND OF THE INVENTION

Electric appliances and electronic appliances emit electromagnetic wave noises, and ambient electromagnetic wave noises intrude into them so that noises are contained in signals. To prevent the emission and intrusion of electromagnetic wave noises, electric appliances and electronic appliances have conventionally been shielded with metal sheets. It is also proposed to dispose magnetic electromagnetic-wave-absorbing films in electric appliances and electronic appliances to absorb electromagnetic wave noises.

For example, JP 2013-42026 A discloses an electromagnetic-wave-absorbing, heat-conductive sheet disposed near devices for transmitting high-frequency signals in electronic appliances, which comprises first magnetic metal particles, and second magnetic metal particles having smaller average particle size and electric resistivity than those of the first magnetic metal particles in a flexible resin. This electromagnetic-wave-absorbing, heat-conductive sheet has high absorbability to electromagnetic wave noise in a wide frequency range, but does not have a function of exhibiting particularly large absorbability to electromagnetic wave noise at a particular frequency, and a function of shifting a frequency range in which the electromagnetic wave noise absorbability is maximized.

### OBJECT OF THE INVENTION

Accordingly, the object of the present invention is to provide an electromagnetic-wave-absorbing composite sheet having high absorbability to electromagnetic wave noises in a desired frequency range, and capable of shifting a frequency range in which electromagnetic wave noise absorbability is maximized.

### DISCLOSURE OF THE INVENTION

As a result of intensive research in view of the above object, the inventor has found that an electromagnetic-wave-absorbing composite sheet having high absorbability to electromagnetic wave noises in a desired frequency range, and capable of shifting a frequency range in which electromagnetic wave noise absorbability is maximized, can be obtained by laminating an electromagnetic-wave-shielding film on an electromagnetic-wave-absorbing magnetic film comprising magnetic powder uniformly dispersed in a binder resin, and setting an area ratio of the electromagnetic-wave-shielding film to the electromagnetic-wave-absorbing magnetic film to 10-80%. The present invention has been completed based on such finding.

Thus, the electromagnetic-wave-absorbing composite sheet of the present invention comprises an electromagnetic-wave-absorbing magnetic film, and an electromagnetic-wave-shielding film laminated on the electromagnetic-wave-absorbing magnetic film;

the electromagnetic-wave-absorbing magnetic film comprising magnetic powder uniformly dispersed in a binder resin; and

an area ratio of the electromagnetic-wave-shielding film to the electromagnetic-wave-absorbing magnetic film being 10-80%.

The area ratio of the electromagnetic-wave-shielding film to the electromagnetic-wave-absorbing magnetic film is preferably 20-80%, more preferably 30-70%, most preferably 40-60%.

The electromagnetic-wave-shielding film is preferably a conductive metal foil, a plastic film having a thin conductive metal film or coating, or a carbon sheet.

The conductive metal in the electromagnetic-wave-shielding film is preferably at least one selected from the group consisting of aluminum, copper, silver, tin, nickel, cobalt, chromium and their alloys.

Both of the electromagnetic-wave-absorbing magnetic film and the electromagnetic-wave-shielding film are preferably in a rectangular or square shape.

### BRIEF DESCRIPTION OF THE DRAWINGS

FIG. 1(a) is an exploded plan view showing an example of the electromagnetic-wave-absorbing composite sheets of the present invention.

FIG. 1(b) is a plan view showing an example of the electromagnetic-wave-absorbing composite sheets of the present invention.

FIG. 2 is a cross-sectional view showing an example of electromagnetic-wave-absorbing magnetic films constituting the electromagnetic-wave-absorbing composite sheet of the present invention.

FIG. 3(a) is a plan view showing another example of the electromagnetic-wave-absorbing composite sheets of the present invention.

FIG. 3(b) is a plan view showing a further example of the electromagnetic-wave-absorbing composite sheets of the present invention.

FIG. 4(a) is a partial plan view showing a system for measuring reflected wave power and transmitted wave power to incident wave.

FIG. 4(b) is a cross-sectional view showing the system of FIG. 4(a).

FIG. 5 is a plan view showing an example of samples placed on a microstripline MSL.

FIG. 6 is a graph showing the noise absorption ratio Pₗₒₛₛ/Pᵢₙ of Sample 1 (area ratio of aluminum foil piece=20%) of the electromagnetic-wave-absorbing composite sheet.

FIG. 7 is a graph showing the noise absorption ratio Pₗₒₛₛ/Pᵢₙ of Sample 2 (area ratio of aluminum foil piece=40%) of the electromagnetic-wave-absorbing composite sheet.

FIG. 8 is a graph showing the noise absorption ratio Pₗₒₛₛ/Pᵢₙ of Sample 3 (area ratio of aluminum foil piece=50%) of the electromagnetic-wave-absorbing composite sheet.

FIG. 9 is a graph showing the noise absorption ratio Pₗₒₛₛ/Pᵢₙ of Sample 4 (area ratio of aluminum foil piece=60%) of the electromagnetic-wave-absorbing composite sheet.

FIG. 10 is a graph showing the noise absorption ratio Pₗₒₛₛ/Pᵢₙ of Sample 5 (area ratio of aluminum foil piece=80%) of the electromagnetic-wave-absorbing composite sheet.

FIG. 11 is a graph showing the noise absorption ratio Pₗₒₛₛ/Pᵢₙ of Sample 6 (area ratio of aluminum foil piece=100%) of the electromagnetic-wave-absorbing composite sheet.

FIG. 12 is a graph showing the noise absorption ratio Pₗₒₛₛ/Pᵢₙ of Sample 11 (D=0 mm) of the electromagnetic-wave-absorbing composite sheet.

FIG. 13 is a graph showing the noise absorption ratio Pₗₒₛₛ/Pᵢₙ of Sample 12 (D=5 mm) of the electromagnetic-wave-absorbing composite sheet.

FIG. 14 is a graph showing the noise absorption ratio Pₗₒₛₛ/Pᵢₙ of Sample 13 (D=10 mm) of the electromagnetic-wave-absorbing composite sheet.

FIG. 15 is a graph showing the noise absorption ratio Pₗₒₛₛ/Pᵢₙ of Sample 14 (D=15 mm) of the electromagnetic-wave-absorbing composite sheet.

FIG. 16 is a graph showing the noise absorption ratio Pₗₒₛₛ/Pᵢₙ of Sample 15 (D=20 mm) of the electromagnetic-wave-absorbing composite sheet.

FIG. 17 is a plan view showing Samples 21 and 22 of the electromagnetic-wave-absorbing composite sheet.

FIG. 18(a) is a graph showing the noise absorption ratio Pₗₒₛₛ/Pᵢₙ of Sample 21 of the electromagnetic-wave-absorbing composite sheet comprising a square aluminum foil piece laminated on a center portion of an electromagnetic-wave-absorbing magnetic film piece.

FIG. 18(b) is a graph showing the noise absorption ratio Pₗₒₛₛ/Pᵢₙ of Sample 22 of the electromagnetic-wave-absorbing composite sheet comprising a square-frame-shaped aluminum foil piece laminated on an electromagnetic-wave-absorbing magnetic film piece.

FIG. 19(a) is a graph showing electromagnetic wave noise leaking from Fire Stick TV, when an IC chip in the Fire Stick TV was covered with the electromagnetic-wave-absorbing composite sheet of Example 4.

FIG. 19(b) is a graph showing electromagnetic wave noise leaking from Fire Stick TV, when an IC chip in the Fire Stick TV was not covered with the electromagnetic-wave-absorbing composite sheet of Example 4.

### DESCRIPTION OF THE PREFERRED EMBODIMENTS

The embodiments of the present invention will be explained in detail referring to the attached drawings, and it should be noted that explanations of one embodiment are applicable to other embodiments unless otherwise mentioned. Also, the following explanations are not restrictive, but various modifications may be made within the scope of the present invention.

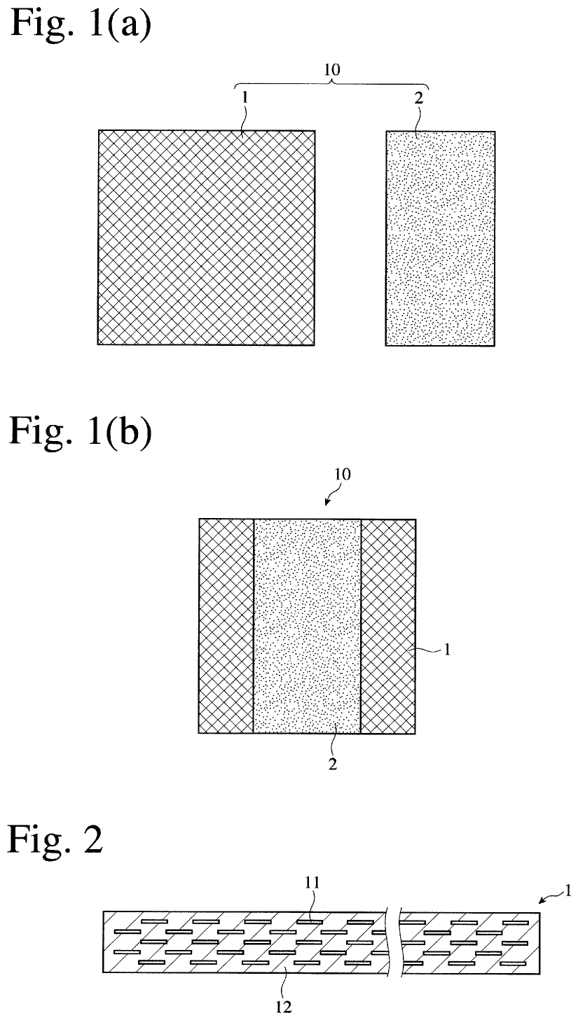

FIG. 1(a) shows an electromagnetic-wave-absorbing magnetic film 1, and an electromagnetic-wave-shielding film 2 laminated on the electromagnetic-wave-absorbing magnetic film 1, which constitute the electromagnetic-wave-absorbing composite sheet 10 of the present invention, and FIG. 1(b) shows an example of the electromagnetic-wave-absorbing composite sheets 10 of the present invention constituted by the electromagnetic-wave-absorbing magnetic film 1 and the electromagnetic-wave-shielding film 2.

[1] Electromagnetic-Wave-Absorbing Magnetic Film

As shown in FIG. 2, the electromagnetic-wave-absorbing magnetic film 1 comprises magnetic powder 11 uniformly dispersed in a binder resin 12.

(1) Magnetic Powder

The magnetic powder 11 may be soft-magnetic metal powder or soft-magnetic ferrite powder.

The soft-magnetic metals include pennalloys (Fe—Ni alloys), super permalloys (Fe—Ni—Mo alloys), Sendusts (Fe—Si—Al alloys), Fe—Si alloys, Fe—Co alloys, Fe—Cr alloys, Fe—Cr—Si alloys, Fe—Si—B(—Cu—Nb) alloys, Fe—Ni—Cr—Si alloys, Fe—Si—Al—Ni—Cr alloys, amorphous Fe alloys, amorphous Co alloys, etc.

The soft-magnetic metal powder is preferably flat. The aspect ratio of the flat soft-magnetic metal powder is preferably 10-100, more preferably 10-50. The average diameter (plane direction) of the flat soft-magnetic metal powder is preferably 30-100 μm, more preferably 50-90 μm. The average thickness of the flat soft-magnetic metal powder is preferably 0.1-1 μm.

The soft-magnetic ferrites include Ni—Zn ferrite, Cu—Zn ferrite, Mn—Zn ferrite, etc. The average particle size of the soft-magnetic ferrite powder is preferably 0.1-30 μm.

(2) Binder Resin

The binder resin 12 having excellent flexibility includes polyolefins such as polyethylene, polypropylene, etc., polyesters such as polyethylene terephthalate, etc., polystyrenes, polyvinyl chloride, acrylic resins, polyurethanes, polycarbonates, polyamides, polyimides, silicone resins, synthetic rubbers, natural rubbers, etc.

(3) Amount of Magnetic Powder

The amount of the magnetic powder 11 in the electromagnetic-wave-absorbing magnetic film 1 is preferably 30% or more by volume, more preferably 30-60% by volume.

(4) Thickness of Electromagnetic-Wave-Absorbing Magnetic Film

The thickness of the electromagnetic-wave-absorbing magnetic film 1 is preferably 0.05-2 mm, more preferably 0.1-1 mm. When the electromagnetic-wave-absorbing magnetic film is thinner than 0.05 mm, sufficient electromagnetic wave absorbability by the magnetic powder cannot be obtained. On the other hand, when it is thicker than 2 mm, the electromagnetic-wave-absorbing composite sheet is too thick.

[2] Electromagnetic-Wave-Shielding Film

To reflect electromagnetic wave noise transmitting the electromagnetic-wave-absorbing magnetic film 1 and project it to the electromagnetic-wave-absorbing magnetic film 1 again, the electromagnetic-wave-shielding film 2 should have a function of reflecting electromagnetic wave noise. To exhibit such function effectively, the electromagnetic-wave-shielding film 2 is preferably a conductive metal foil, a plastic film having a thin conductive metal film or coating, or a carbon sheet. The electromagnetic-wave-absorbing magnetic film 1 and the electromagnetic-wave-shielding film 2 are preferably laminated via a non-conductive adhesive, which may be a known one.

(1) Conductive Metal Foil

The conductive metal is preferably at least one selected from the group consisting of aluminum, copper, silver, tin, nickel, cobalt, chromium, and their alloys. The conductive metal foil is preferably as thick as 5-50 μm.

(2) Thin Conductive Metal Film or Coating

The thin conductive metal film is preferably a vapor-deposited film of the above conductive metal. The vapor-deposited metal film may be as thick as several tens of nanometers to several tens of micrometers. The plastic film, on which a vapor-deposited film of the above conductive metal is formed, is not particularly restrictive as long as they have sufficient strength, flexibility and workability in addition to insulation, and it may be made of, for instance, polyesters (polyethylene terephthalate, etc.), polyarylene sulfide (polyphenylene sulfide, etc.), polyamides, polyimides, polyamideimides, polyether sulfone, polyetheretherketone, polycarbonates, acrylic resins, polystyrenes, polyolefins (polyethylene, polypropylene, etc.), etc. From the aspect of strength and cost, polyethylene terephthalate (PET) is preferable. The thickness of the plastic film may be about 8-30 μm.

(3) Conductive Metal Coating

The conductive metal coating can be formed by coating a plastic film with an ink (paste) comprising conductive metal powder such as silver powder, etc. highly dispersed in a thermoplastic or photocuring resin, drying the resultant coating, and then irradiating the coating with ultraviolet rays, if necessary. The conductive ink (paste) may be a known one, for example, a photocuring, conductive ink composition (JP 2016-14111 A) comprising a conductive filler, a photoinitiator, and a polymer dispersant, the percentage of the conductive filler being 70-90% by mass; and the conductive filler being silver powder having a particle size D₅₀ of 0.3-3.0 μm, 50% or more by mass of which is in a scale, foil or flake shape. The plastic film on which the conductive metal is coated may be the same as the plastic film on which the thin conductive metal film is deposited.

(4) Carbon Sheet

The carbon sheet used as the electromagnetic-wave-shielding film may be a commercially available PGS (registered trademark) graphite sheet (available from Panasonic Corporation) formed by heat-treating a polyimide film at an ultrahigh temperature in an inert gas, a carbon sheet (heat dissipation sheet) comprising graphite powder and carbon black, etc.

Usable as a carbon sheet of graphite powder/carbon black is a heat dissipation sheet (JP 2015-170660 A) having a structure in which carbon black is uniformly dispersed among fine graphite particles, with a mass ratio of fine graphite particles/carbon black of 75/25-95/5, a density of 1.9 g/cm³ or more, and an in-plane thermal conductivity of 570 W/mK or more. The fine graphite particles preferably have an average diameter of 5-100 μm and an average thickness of 200 nm or more. This heat dissipation sheet is preferably as thick as 25-250 μm.

This heat dissipation sheet can be formed by a method comprising (1) preparing a dispersion containing 5-25% by mass in total of fine graphite particles and carbon black, and 0.05-2.5% by mass of a binder resin in an organic solvent, a mass ratio of the fine graphite particles to the carbon black being 75/25-95/5; (2) repeating a step of applying the dispersion to a surface of a support plate and a drying step plural times, to form a resin-containing composite sheet comprising the fine graphite particles, the carbon black, and the binder resin; (3) burning the resin-containing composite sheet to remove the binder resin; and (4) pressing the resultant composite sheet of fine graphite particles/carbon black for densification.

[3] Arrangement of Electromagnetic-Wave-Absorbing Magnetic Film and Electromagnetic-Wave-Shielding Film

(1) Area Ratio

An area ratio of the electromagnetic-wave-shielding film 2 to the electromagnetic-wave-absorbing magnetic film 1 is 10-80%. When the area ratio is less than 10% or more than 80%, the absorbability of electromagnetic wave noise in a desired frequency range is not sufficiently maximized. This is an unexpected result, and it is an important feature of the present invention that the area ratio of the electromagnetic-wave-shielding film 2 to the electromagnetic-wave-absorbing magnetic film 1 is 10-80%. The lower limit of the area ratio is preferably 20%, more preferably 30%, further preferably 40%, most preferably 45%. The upper limit of the area ratio is preferably 70%, more preferably 65%, most preferably 60%. The area ratio range of the electromagnetic-wave-shielding film 2 to the electromagnetic-wave-absorbing magnetic film 1 is, for example, preferably 20-80%, more preferably 30-70%, further preferably 40-65%, most preferably 45-60%.

(2) Position

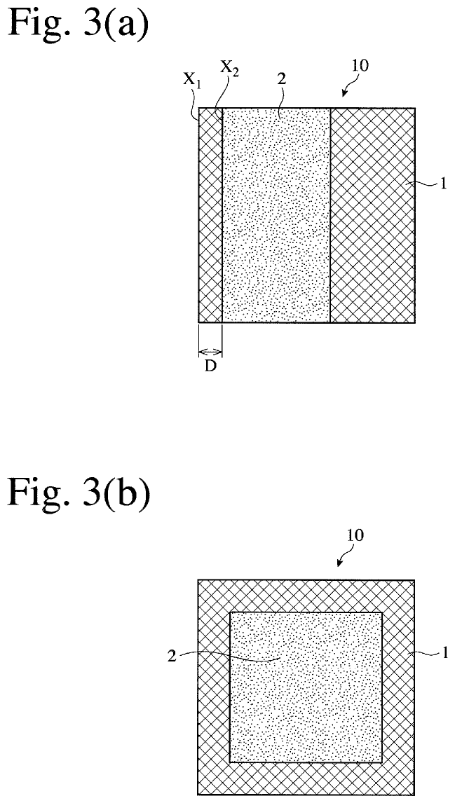

A center of the electromagnetic-wave-shielding film 2 is preferably positioned at a center of the electromagnetic-wave-absorbing magnetic film 1, but it may be deviated to change a frequency at which the electromagnetic wave absorbability has a peak. The position change of the electromagnetic-wave-shielding film 2 may be conducted by shifting the electromagnetic-wave-shielding film 2 in one direction relative to the electromagnetic-wave-absorbing magnetic film 1 as shown in FIG. 3(a), or by reducing the size of the electromagnetic-wave-shielding film 2 such that four sides of the electromagnetic-wave-shielding film 2 are receding inward from four sides of the electromagnetic-wave-absorbing magnetic film 1 as shown in FIG. 3(b). In both cases, because how the electromagnetic-wave-shielding film 2 is shifted or sized relative to the electromagnetic-wave-absorbing magnetic film 1 affects a frequency at which the electromagnetic wave absorbability has a peak, it is preferably determined depending on a frequency range in which the electromagnetic wave absorbability is maximized. In any of FIGS. 3(a) and 3(b), the area ratio of the electromagnetic-wave-shielding film 2 to the electromagnetic-wave-absorbing magnetic film 1 should meet the above requirement.

The present invention will be explained in more detail referring to Examples below without intention of restricting the present invention thereto.

### EXAMPLE 1

Each of electromagnetic-wave-absorbing magnetic film pieces 1 of 50 mm×50 mm were cut out of a commercially available noise absorption sheet (NOISEFUSEGU 10S, WW-GM10-S available from Wide Work Corporation, thickness: 1 mm) was laminated with each of aluminum foil pieces (thickness: 15 μm) 2 having sizes of L (10 mm, 20 mm, 25 mm, 30 mm, 40 mm, and 50 mm)×50 mm via a non-conductive adhesive, to produce Samples 1-6. In each Sample, a center of the aluminum foil piece 2 was aligned with a center of the electromagnetic-wave-absorbing magnetic film piece 1.

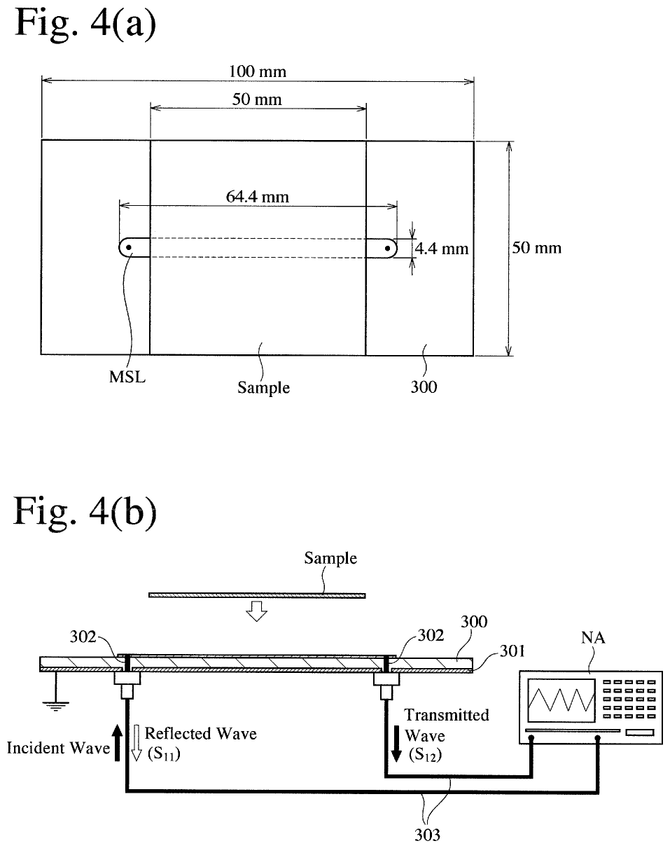

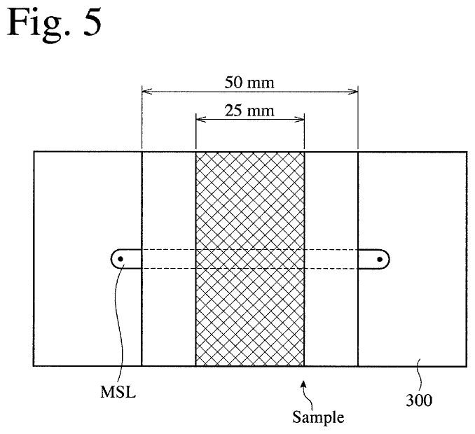

Using a system comprising a microstripline MSL (64.4 mm×4.4 mm) of 50Ω, an insulation substrate 300 supporting the microstripline MSL, a grounded electrode 301 attached to a lower surface of the insulation substrate 300, conductor pins 302, 302 connected to both ends of the microstripline MSL, a network analyzer NA, and coaxial cables 303, 303 connecting the network analyzer NA to the conductor pins 302, 302 as shown in FIGS. 4(a) and 4(b), each sample was attached to an upper surface of the insulation substrate 300 by an adhesive such that a center of each sample was aligned with a center of the microstripline MSL as shown in FIG. 5, to measure reflected wave power S11 and transmitted wave power S₁₂ to incident waves of 0.1-6 GHz.

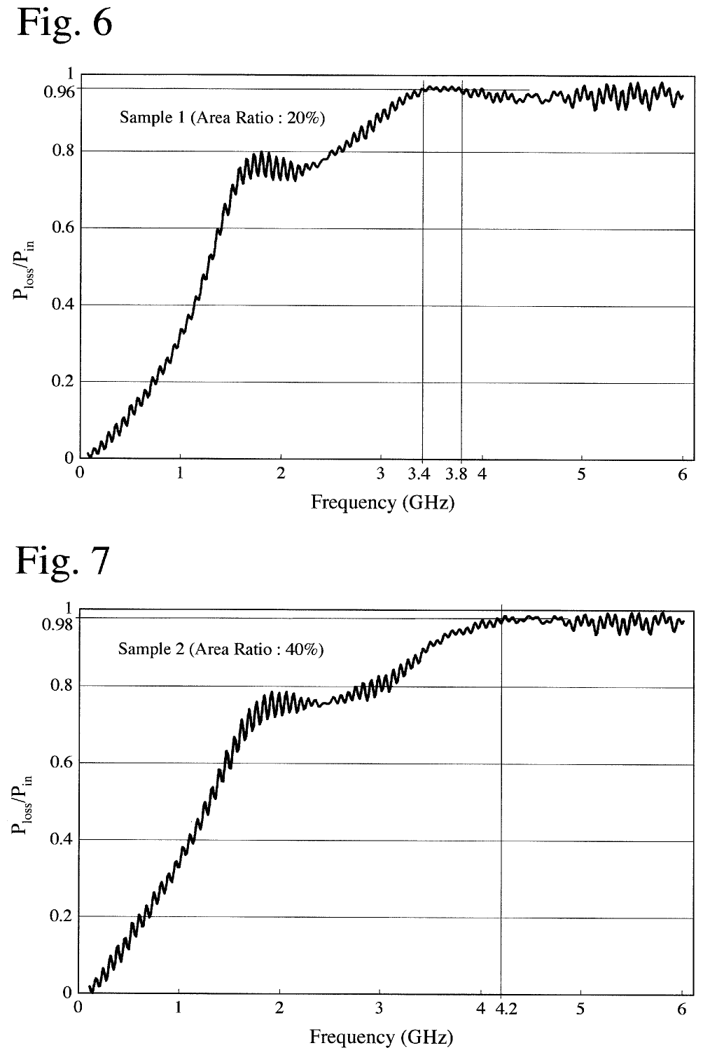

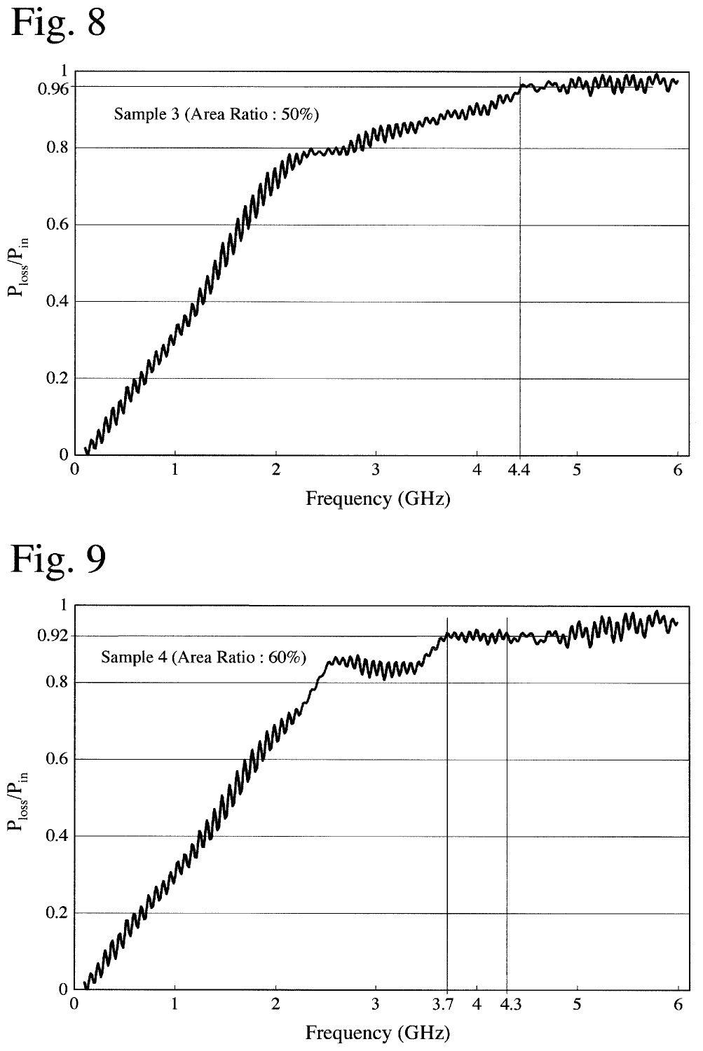

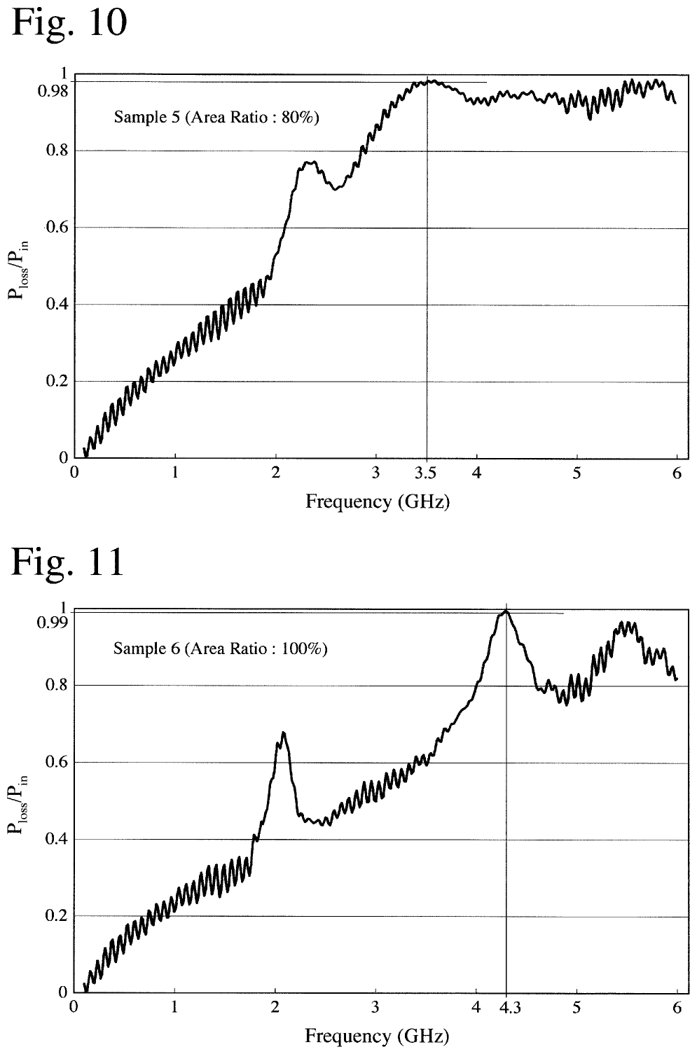

Power loss Pₗₒₛₛ was determined by subtracting the reflected wave power S₁₁ and the transmitted wave power S₁₂ from the incident power Pᵢₙ input to the system shown in FIGS. 4(a) and 4(b), and a noise absorption ratio Pₗₒₛₛ/Pᵢₙ was determined by dividing Pₗₒₛₛ by the incident power Pᵢₙ. The results are shown in FIGS. 6 to 11 and Table 1.

TABLE 1

| | |
|---|---|
| Aluminum Foil | Maximum Noise |
| Piece | Absorption |

| Sample | L | Area Ratio ⁽¹⁾ | | Frequency |
|---|---|---|---|---|
| No. | (mm) | (%) | Pₗₒₛₛ/Pᵢₙ | (GHz) |
| 1 | 10 | 20 | 0.96 | 3.4-3.8 |
| 2 | 20 | 40 | 0.98 | 4.2 |
| 3 | 25 | 50 | 0.96 | 4.4 |
| 4 | 30 | 60 | 0.92 | 3.7-4.3 |
| 5 | 40 | 80 | 0.98 | 3.5 |
| 6* | 50 | 100 | 0.99 | 4.3 |

Note:
⁽¹⁾ An area ratio of the aluminum foil piece to the electromagnetic-wave-absorbing magnetic film piece.
Sample with * is Comparative Example.

In Sample 6 having an electromagnetic-wave-absorbing magnetic film piece on which an aluminum foil piece of the same size was laminated, the noise absorption ratio Pₗₒₛₛ/Pᵢₙ was low as a whole, despite a high maximum noise absorption ratio Pₗₒₛₛ/Pᵢₙ at limited frequencies. On the other hand, in Samples 1-5 each having an aluminum foil piece with an area ratio of 20-80% laminated on the electromagnetic-wave-absorbing magnetic film piece, the maximum noise absorption ratios Pₗₒₛₛ/Pᵢₙ were as high as 0.92-1.00, and frequencies at them were around 3 GHz. It is thus clear that to maximize the noise absorption ratio Pₗₒₛₛ/Pᵢₙ in a frequency range near 3 GHz, the area ratio of the aluminum foil piece (electromagnetic-wave-shielding film) to the electromagnetic-wave-absorbing magnetic film piece should be in a range of 10-80%, and is preferably in a range of 20-80%.

### EXAMPLE 2

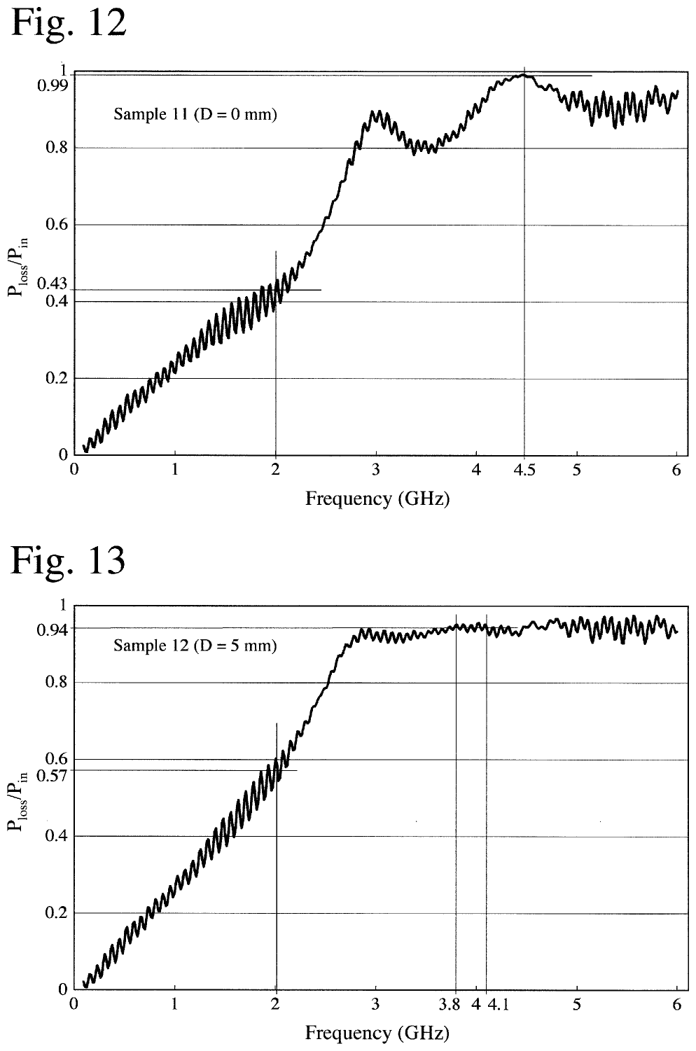

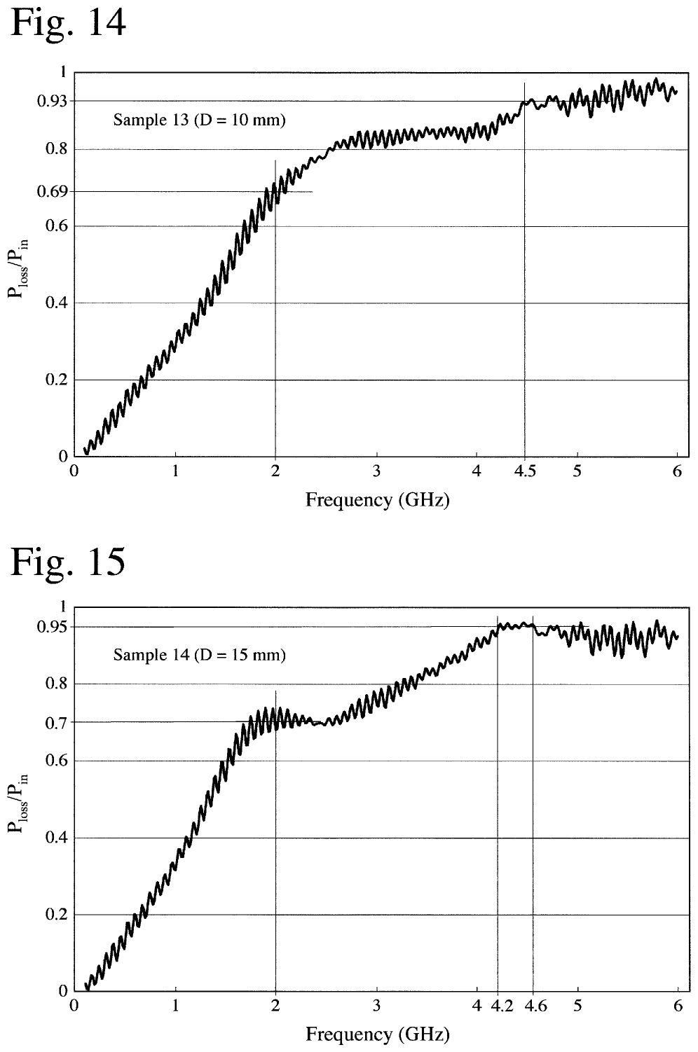

An aluminum foil piece (thickness: 15 μm) of 25 mm×50 mm was laminated via a non-conductive adhesive on the electromagnetic-wave-absorbing magnetic film piece of 50 mm×50 mm used in Example 1, such that the distance D between one side X₁ of the electromagnetic-wave-absorbing magnetic film piece and one side X₂ (parallel to X₁) of the aluminum foil piece was 0 mm, 5 mm, 10 mm, 15 mm, and 20 mm, respectively, as shown in FIG. 3(a), to produce Samples 11-15. Each sample was placed on the microstripline MSL on the insulation substrate 300 as shown in FIG. 5, to measure its noise absorption ratio Pₗₒₛₛ/Pᵢₙ in a range of 0.1-6 GHz. The results are shown in FIGS. 12-16. Also, with respect to each sample, the distance D, the noise absorption ratio Pₗₒₛₛ/Pᵢₙ at 2 GHz, the maximum noise absorption ratio Pₗₒₛₛ/Pᵢₙ, and a frequency at the maximum noise absorption ratio were measured. The results are shown in Table 2.

TABLE 2

| Sample | D ⁽¹⁾ | Pₗₒₛₛ/Pᵢₙ | Maximum Pₗₒₛₛ/Pᵢₙ | |
|---|---|---|---|---|
| No. | (mm) | at 2 GHz | (GHz) | |
| 11 | 0 | 0.43 | 0.99 | (4.5) |
| 12 | 5 | 0.57 | 0.94 | (3.8-4.1) |
| 13 | 10 | 0.69 | 0.93 | (4.5) |
| 14 | 15 | 0.70 | 0.95 | (4.2-4.6) |
| 15 | 20 | 0.66 | 0.96 | (3.9) |

Note:
⁽¹⁾ D represents the distance between one side X₁ of the electromagnetic-wave-absorbing magnetic film piece and one side X₂ of the aluminum foil piece.

As is clear from FIGS. 12-16 and Table 2, as the aluminum foil piece was shifted relative to the electromagnetic-wave-absorbing magnetic film piece, the Pₗₒₛₛ/Pᵢₙ at 2 GHz and the maximum Pₗₒₛₛ/Pᵢₙ, changed drastically. This indicates that to maximize the noise absorption ratio Pₗₒₛₛ/Pᵢₙ in a desired frequency range, a center of the aluminum foil piece need only be deviated from a center of the electromagnetic-wave-absorbing magnetic film piece.

### EXAMPLE 3

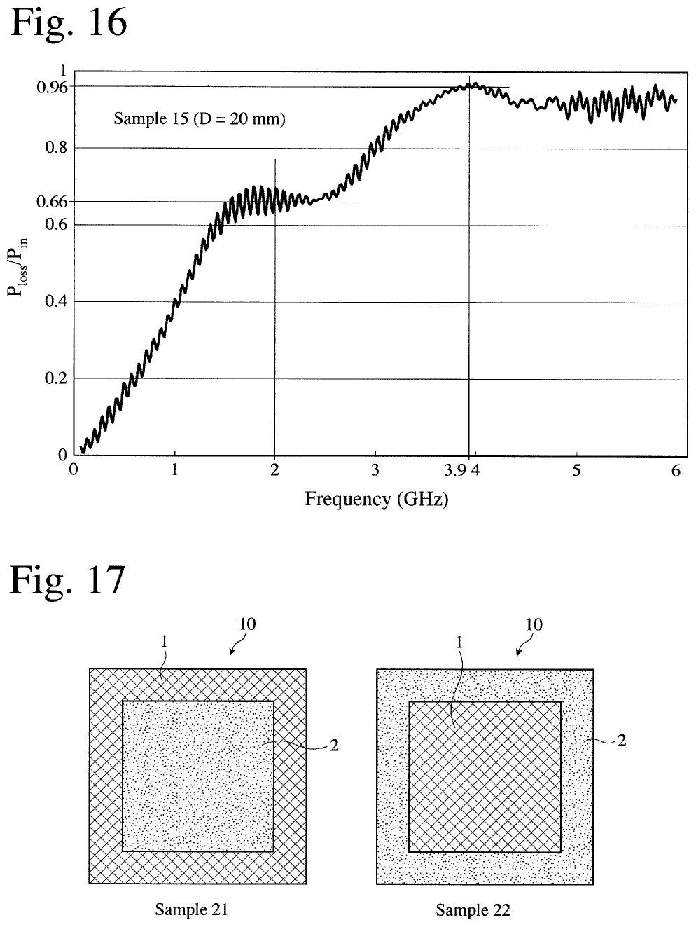

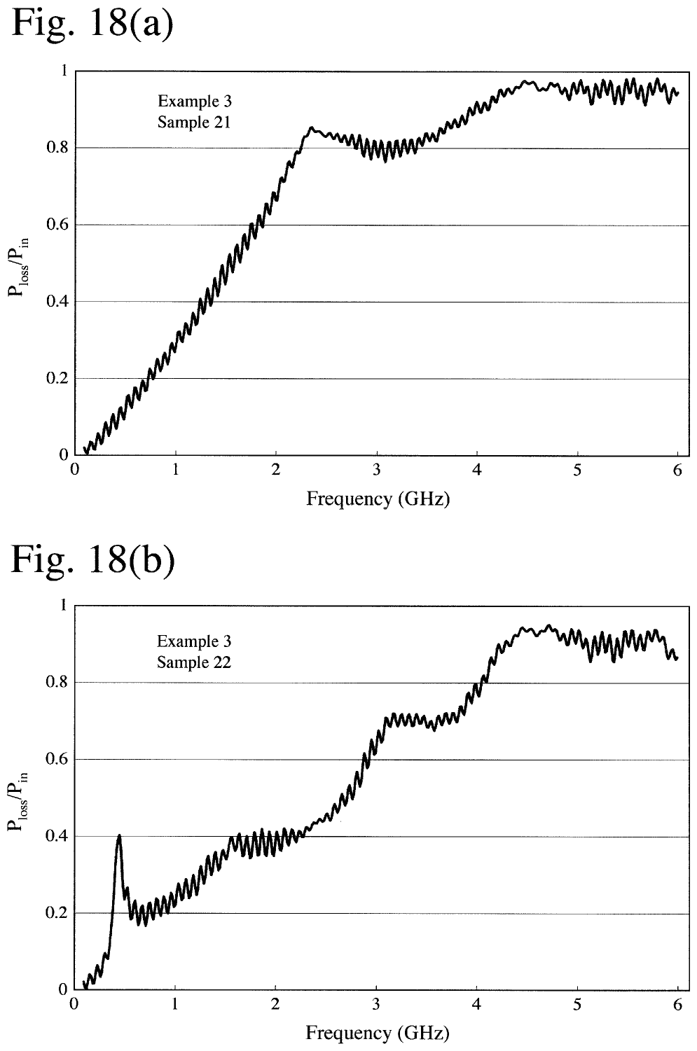

As shown in FIG. 17, a square aluminum foil piece having an area ratio of 50%, and a square-frame-shaped aluminum foil piece having an area ratio of 50% were laminated on the same electromagnetic-wave-absorbing magnetic film piece of 50 mm×50 mm as in Example 1, such that their centers were aligned, to produce Samples 21 and 22. The noise absorption ratio Pₗₒₛₛ/Pᵢₙ of each sample was measured. The measurement results are shown in FIGS. 18(a) and 18(b).

As is clear from FIGS. 18(a) and 18(b), Sample 21 laminated with a square aluminum foil piece having an area ratio of 50% exhibited an extremely higher noise absorption ratio Pₗₒₛₛ/Pᵢₙ than that of Sample 22 laminated with the square-frame-shaped aluminum foil piece, despite the same area ratio. This indicates that the aluminum foil piece is preferably positioned in a center portion of the electromagnetic-wave-absorbing magnetic film piece.

### EXAMPLE 4

A square electromagnetic-wave-absorbing composite sheet as large as an IC chip in Fire Stick TV of Amazon, which had the same structure as in Example 1, was produced. A rectangular aluminum foil piece had an area ratio of 50% to the electromagnetic-wave-absorbing magnetic film piece. One pair of opposing sides of the aluminum foil piece were aligned with one pair of opposing sides of the electromagnetic-wave-absorbing magnetic film piece, and a center of the laminated aluminum foil piece was aligned with a center of the electromagnetic-wave-absorbing magnetic film piece. Namely, the electromagnetic-wave-absorbing composite sheet of Example 4 had the shape shown in FIG. 1(b).

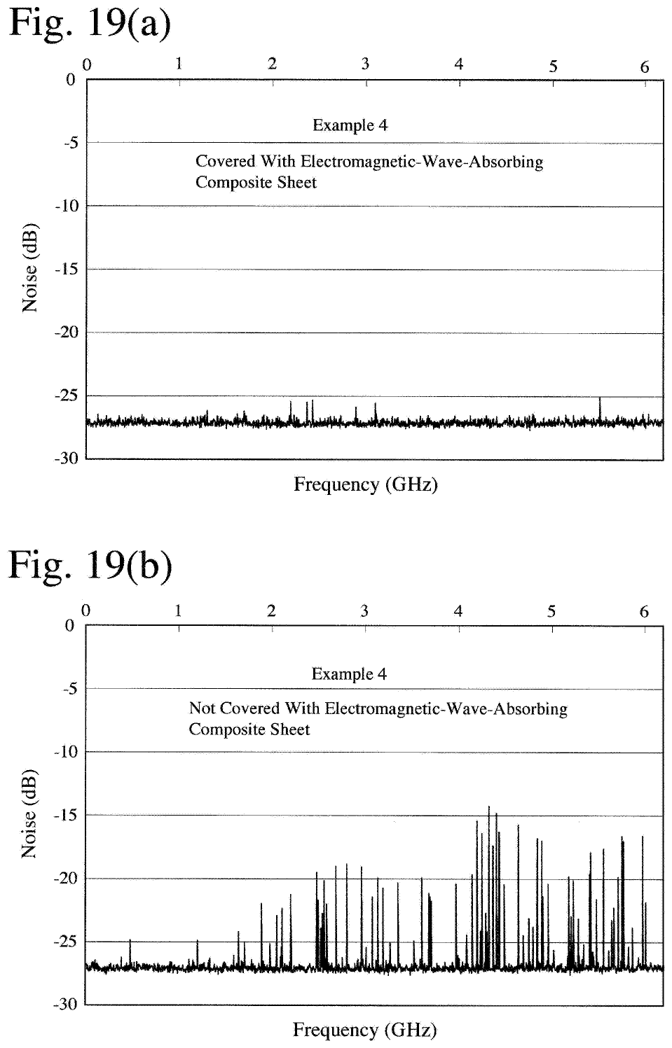

With a cover removed from the Fire Stick TV, the electromagnetic-wave-absorbing composite sheet of Example 4 was placed on the IC chip in the Fire Stick TV, to measure electromagnetic wave noise leaking from the Fire Stick TV by a spectrum analyzer VSA6G2A available from Keisoku Giken Co., Ltd. The results are shown in FIG. 19(a). Also, electromagnetic wave noise leaking from the Fire Stick TV was measured, when the electromagnetic-wave-absorbing composite sheet of Example 4 was not placed on the IC chip in the Fire Stick TV, from which a cover was removed. The results are shown in FIG. 19(b). As is clear from FIGS. 19(a) and 19(b), electromagnetic wave noise at a frequency of around 3 GHz leaking from the Fire Stick TV remarkably decreased when the electromagnetic-wave-absorbing composite sheet of the present invention was placed on the IC chip, than when no electromagnetic-wave-absorbing composite sheet was placed.

Though electromagnetic-wave-absorbing composite sheets having aluminum foils laminated as electromagnetic-wave-shielding films on electromagnetic-wave-absorbing magnetic films are used in Examples above, the present invention is not restricted to these electromagnetic-wave-absorbing composite sheets, but may be modified within its scope. In addition to the aluminum foil, a copper foil, and coatings of conductive inks containing dispersed powder of aluminum, copper, silver, etc. are also usable as the electromagnetic-wave-shielding film.

### EFFECTS OF THE INVENTION

The electromagnetic-wave-absorbing composite sheet of the present invention having the above structure has excellent electromagnetic wave absorbability, and can maximize electromagnetic wave noise absorbability in a desired frequency range by changing an area ratio of an electromagnetic-wave-shielding film to an electromagnetic-wave-absorbing film within a range of 10-80%.

### DESCRIPTION OF REFERENCE NUMERALS

1: Electromagnetic-wave-absorbing magnetic film

2: Electromagnetic-wave-shielding film

10: Electromagnetic-wave-absorbing composite sheet

11: Magnetic powder

12: Binder resin

300: Insulation substrate

301: Grounded electrode

302: Conductor pin

303: Coaxial cable

D: Distance between one side X₁ of electromagnetic-wave-absorbing magnetic film piece and one side X₂ of aluminum foil (electromagnetic-wave-shielding film) piece

MSL: Microstripline

NA: Network analyzer

What is claimed is:

1. An electromagnetic-wave-absorbing composite sheet comprising an electromagnetic-wave-absorbing magnetic film, and an electromagnetic-wave-shielding film laminated on said electromagnetic-wave-absorbing magnetic film;
said electromagnetic-wave-absorbing magnetic film comprising magnetic powder uniformly dispersed in a binder resin; and
an area ratio of said electromagnetic-wave-shielding film to said electromagnetic-wave-absorbing magnetic film being 10-80%.

2. The electromagnetic-wave-absorbing composite sheet according to claim 1, wherein the area ratio of said electromagnetic-wave-shielding film to said electromagnetic-wave-absorbing magnetic film is 20-80%.

3. The electromagnetic-wave-absorbing composite sheet according to claim 1, wherein said electromagnetic-wave-shielding film is a conductive metal foil, a plastic film having a thin conductive metal film or coating, or a carbon sheet.

4. The electromagnetic-wave-absorbing composite sheet according to claim 1, wherein both of said electromagnetic-wave-absorbing magnetic film and said electromagnetic-wave-shielding film are in a rectangular or square shape.
